(19) United States
(12) Patent Application Publication
(10) Pub. No.: US 2024/0094394 A1
(43) Pub. Date: Mar. 21, 2024

(54) MULTIPLE-FREQUENCY-COMPONENT SCANNING INVOLVING SCAN-PATTERN DESIGN AND BALANCED OR OPTIMIZED ATTRIBUTES

(71) Applicant: The Board of Trustees of the Leland Stanford Junior University, Stanford, CA (US)

(72) Inventors: Zhanghao Sun, Mountain View, CA (US); Ronald Quan, Cupertino, CA (US); Olav Solgaard, Stanford, CA (US)

(21) Appl. No.: 18/273,735

(22) PCT Filed: Jan. 27, 2022
(86) PCT No.: PCT/US2022/014001

§ 371 Date: Jul. 21, 2023

Related U.S. Application Data
(60) Provisional application No. 63/142,969, filed on Jan. 28, 2021.

(51) Int. Cl. G01S 17/89; B81B 7/02; G01S 7/481

(52) U.S. Cl. CPC G01S 17/89; B81B 7/02; G01S 7/4817

(57) ABSTRACT

In certain examples, methods and apparatuses, such as circuits, are directed to scanning in a field of view (FoV) by using a pattern that improves sensing in a region of interest (RoI) within the FoV. In one example, a signal having multiple frequency components and a scan-pattern design are used, with a balanced or optimized set of attributes including a sampling density attribute, to scan a RoI in a FoV by sampling or traversing the RoI more times than other regions in the FoV. In more specific examples, circuitry finds the scan-pattern design based on an algorithm that processes different parameters involving at least one of amplitude and phase and processes a. number of different frequency components related to or including the multiple frequency components, wherein the number of different frequency components is from three to a threshold limit whereat processing different frequency components provides negligible improvement.

### BACKGROUND

Aspects of the present disclosure are related generally to the field of fast-spatial scanners, for example, including radar-type scanners and including, but not necessarily limited to, those using light beams or pulsed light technologies (e.g., light detection and ranging or “LiDAR” time-of-flight distance sensing), wherein signals are generated and used by a spatial scanner for sensing objects within the scanner's field of view.

In recent years, there has been the rapid development of fast-spatial scanners in robotics, autonomous vehicles and other applications benefiting from fast-spatial scanning. Designing accurate and efficient scanning systems has been challenging in terms of both hardware (i.e., circuitry) and software since real-time response requires very fast information collection and processing. For ease of discussion, LiDAR is used as one such technology type which involves optical scanning to send (e.g., deflect) one or more laser beams onto different sampling positions in space and from which 3D data is to be acquired for analysis of any objects which may be in that scanned space.

A more specific example is a LiDAR scanner which uses a resonant-type scanner that employs a Lissajous scanning. Such a resonant-type scanner is typically characterized in an opto-mechanical system involving use of two distinct scanning axes to provide a well-known advantage: when actuated at resonant frequency, the motion amplitude of a resonant scanner is ˜Q times larger than that of a raster scanner, where Q is the quality factor of the resonant scanner. Also, the resonant scanner's speed is greatly improved (e.g., much higher than that of a raster scanner which acquires data in a prescribed sequential pattern that is limited by the speed of its slow axis).

Many real-world applications demand ever-increasing speeds of spatial sampling and accuracy in terms of ability to provide a realistic assessment of objects in selected fields of view.

### SUMMARY OF VARIOUS ASPECTS AND EXAMPLES

Various examples/embodiments presented in this disclosure are directed to issues such as those addressed above and/or others which may become apparent from the following disclosure. For example, some of these disclosed aspects are directed to scanning methods and devices that use or leverage from use of multiple frequencies to improve the responsiveness or flexibility of the scanning in a region of interest (RoI) within a field of view (FoV).

In certain examples, methods and apparatuses, such as circuits, disclosed herein are directed to scanning in a FoV by using a pattern that improves sensing in an RoI within the FoV. In one specific example, a signal having multiple frequency components and a scan-pattern design are used, with a balanced or optimized set of attributes including a sampling density attribute, to scan (e.g., for providing focus for) a RoI in a FoV by sampling or traversing the RoI more times than other regions in the FoV. In some instances, the sampling density attribute for a particular RoI in the FoV may be appreciated, for example, relative to characterizing by way of a fill factor which may be used in certain contexts to associate with sampled points distributed throughout the entire FoV (or in some cases throughout a square or rectangular area).

In related and more-specific examples, the present disclosure is directed to circuitry which is configured (e.g., programmed) to find the scan-pattern design based on an algorithm that processes different parameters involving at least one of amplitude and phase and processes a number of different frequency components related to or including the multiple frequency components, wherein the number of different frequency components is from the minimum number being three to a threshold limit whereat processing different frequency components provides negligible improvement (and in some instances, this minimum number is two).

In one specific example that builds on one or more of the above examples, the present disclosure is directed to an apparatus, such as a circuit-based device, and a method for using the apparatus, involving signal processing circuitry which may be used to scan in a FoV by using a pattern that improves sensing in a region of interest (RoI) within the FoV. The signal, having multiple frequency components, is used with a particular scan-pattern design and with a balanced or optimized set of attributes including a sampling density attribute, may be used to scan a RoI in a FoV by sampling or traversing the RoI more times than other regions in the FoV. In related more-specific examples, such scanning circuitry finds the scan-pattern design based on an algorithm that processes different parameters involving at least one of amplitude and phase and processes a number of different frequency components related to or including the multiple frequency components, wherein the number of different frequency components is from three to a threshold limit (e.g., from five to a number less than ten) where this threshold limit is deemed as at point at which processing an increased number of different frequency components for the specific application or implementation provides negligible improvement.

In certain other examples which may also build on the above examples and/or aspects, methods and apparatus are directed to one or more of the following: the resonant frequencies being within a predetermined or resonance bandwidth of the scanning frequencies in the signal; finding the scan-pattern design based on a task-driven algorithm that varies scan-patterns variables according to different possible scan regions in the FoV; and finding the scan-pattern design as being optimal for the RoI, and in response, providing concentrated spatial sampling or traversing for the RoI.

Another aspect of the present disclosure is directed to a method, and/or circuitry that may be used with such a method, in which the circuitry generates or provides a scan-pattern design with a balanced or optimized set of attributes including a sampling density attribute. The scan-pattern design may be generated by the circuitry, or may be provided previously (e.g., from with the scanning circuitry and/or by another processing circuit before being acquired by the scanning circuitry). The design may be configured or optimized for use with a signal having multiple frequency components, such that the signal and the scan-pattern design are cooperatively configured to scan such a RoI in a field of view (including the RoI) by sampling or traversing the RoI more times than other regions in the field of view. In this context, the scanning effort may hone in on, or focus on, possible objects in the RoI, by gathering more samples from that region versus other regions in the field of view.

The above discussion is not intended to describe each aspect, embodiment or every implementation of the present disclosure. The figures and detailed description that follow also exemplify various embodiments.

### BRIEF DESCRIPTION OF FIGURES

Various examples, including experimental examples, may be more completely understood in consideration of the following detailed description and in connection with the accompanying drawings, each in accordance with the present disclosure, in which:

FIG. 1A shows a block diagram, including two sub-blocks which may be used separately or together and which are used to illustrate certain exemplary scanning apparatuses with methodology and certain aspects according to the present disclosure;

FIG. 1B is diagram illustrating different types of scanning patterns including those associated with single-frequency scan signals and multiple-frequency scan signals, the latter of which are described as being useful for certain exemplary scanning apparatuses and methodology consistent with aspects of the present disclosure;

FIGS. 2A, 2B show qualitative comparisons of patterns relevant to certain more-specific experimental-type embodiments of the present disclosure, with FIG. 2A including illustrations of baseline and optimized patterns, and object-detection estimations of use of these patterns, FIG. 2B including optimized patterns, visualization of optimization process, and depth inpainting estimations of use of these patterns; and

FIGS. 3A, 3B, 3C, 3D and 3E show more-specific/experimental-type embodiments also according to the present disclosure, with FIG. 3A showing block diagram, FIG. 3B showing related phase-control estimations associated therewith, FIG. 3C showing recorded scanning patterns for such an embodiment, FIG. 3D showing recorded scanning patterns involving a single-frequency embodiment, and FIG. 3E showing comparison recorded patterns related to these embodiments.

While various embodiments discussed herein are amenable to modifications and alternative forms, aspects thereof have been shown by way of example in the drawings and will be described in detail. It should be understood, however, that the intention is not to limit the disclosure to the particular embodiments described. On the contrary, the intention is to cover all modifications, equivalents, and alternatives falling within the scope of the disclosure including aspects defined in the claims.

### DETAILED DESCRIPTION

Aspects of the present disclosure are believed to be applicable to a variety of different types of apparatuses, systems and methods involving devices useful for scanning in a field of view (FoV) by using a pattern that improves sensing in a region of interest (RoI) within the FoV, and where the scanning signal stems from using multiple frequency components and/or a scan-pattern design that may be found or selected for the RoI. While the present disclosure is not necessarily limited to such aspects, an understanding of specific examples in the following description may be understood from discussion in such specific contexts.

Accordingly, in the following description various specific details are set forth to describe specific examples presented herein. It should be apparent to one skilled in the art, however, that one or more other examples and/or variations of these examples may be practiced without all the specific details given below. In other instances, well known features have not been described in detail so as not to obscure the description of the examples herein. For ease of illustration, the same connotation and/or reference numerals may be used in different diagrams to refer to the same elements or additional instances of the same element. Also, although aspects and features may in some cases be described in individual figures, it will be appreciated that features from one figure or embodiment can be combined with features of another figure or embodiment even though the combination is not explicitly shown or explicitly described as a combination.

Consistent with the present disclosure, such devices and/or methods may be used in connection with, among other example applications not necessarily disclosed herein, fast-spatial scanners for use in and/or integrated as part of circuit-based apparatuses applied or relating to robotics, proximity sensing of another object (e.g., whether at a fixed distance or relative to movement between the objects), autonomous vehicles and other applications benefiting from fast-spatial scanning. Other applications may include, as further examples: 3D computer vision-related tasks and implementations; various wide-band actuation and control systems; resonant scanners such as in high frame-rate LiDAR systems; corresponding to the exemplary discussions of pattern design; scanners with different resonant frequencies and/or with different modes of operation; general-purpose spatial sampling with good field-of-view coverage; and regions-of-Interest focused sampling for specific vision tasks. Also, certain optimization framework exemplified in the present disclosure is not limited to resonant scanning patterns and can be generalized to other spatial sampling scenarios.

Consistent with the above aspects, such a manufactured device or method of such manufacture may involve aspects presented and claimed in U.S. Provisional Application Ser. No. 63/142,969 filed on Jan. 28, 2021 (S20-531) with Appendices, to which priority is claimed. To the extent permitted, such subject matter is incorporated by reference in its entirety generally and to the extent that further aspects and examples (such as experimental and/more-detailed embodiments) may be useful to supplement and/or clarify.

As noted above, certain exemplary aspects of the present disclosure involve methodology and structures directed to scanning in a field of view (FoV) by using a pattern that improves sampling in a region of interest (RoI) within the FoV, and where the scanning signal stems from using multiple frequency components and/or a scan-pattern design that may be found or selected for the RoI. Consistent therewith, certain example embodiments of the present disclosure are directed to methods and apparatuses (e.g., circuits or scanning systems) involving configurations or uses of the apparatus for scanning in a FoV by using a pattern that balances or optimizes a set of attributes including a sampling density attribute for a RoI in the FoV.

According to one exemplary method, a type of embodiment of the present disclosure provides (or accesses) a signal having multiple frequency components and a scan-pattern design for effective scanning of the FoV. The scan-pattern design, and in certain instances the signal also, has a balanced or an optimized set of attributes including a sampling density attribute. The balanced or preferably optimized attributes (e.g., optimized to a degree for a specific application) are used to scan a RoI in the FoV by sampling or traversing the RoI more times than other regions in the FoV. In more specific examples directed to exemplary methodology (e.g., via programmed processing circuitry) according to the present disclosure, a first step is to find the scan-pattern design based on an algorithm that processes different parameters involving at least one of amplitude and phase and processes a number of different frequency components related to or including the multiple frequency components. The number of different frequency components may be from three to a threshold limit (such as five, six or seven) whereat processing different frequency components provides negligible improvement. In addition to a sampling density attribute, the set of attributes which are balanced and/or optimized, may include a scanning-range attribute, and other types of attributes such as resonant frequency ratio, adjustments on phase shift (even if slight), fill-factor (as discussed earlier) and sampling uniformity.

Another aspect of the present disclosure is directed to a method, or a circuit that may be used with such a method, in which the circuitry generates or provides a scan-pattern design with a balanced or optimized set of attributes including a sampling density attribute. In one example, the scan-pattern design may be generated and then used (e.g., by a CPU accessing the design as stored in a tangible or non-transitory storage medium) by processing and/or scanning circuitry in connection with scanning procedures consistent with examples and aspects of the present disclosure. In such examples, the scan-pattern design may be generated by the circuitry (whether previously provided or generated by the same scanner) such that it is configured or optimized for use with a signal having multiple frequency components, wherein the signal and the scan-pattern design are cooperatively configured to scan such a RoI in a field of view (including the RoI) by sampling or traversing the RoI more times than other regions in the field of view. In this context, the scanning effort may hone in on (i.e., focus on) possible objects in the RoI, by gathering more samples from that region versus other regions in the field of view.

According to certain more specific examples, the present disclosure is directed to scanning-related circuitry (e.g., data processing, signal generation, radar sampling) and to methodology involving a semiconductive structure (e.g., circuit-based structure) device having aspects as characterized by the present disclosure. As will be apparent from general and more-specific discussion and/or illustration herein, other aspects and examples of the present disclosure may be used to build on or more of the above-discussed aspects. Such aspects and examples may include one or more of the following: finding the scan-pattern design based on an algorithm that processes different parameters involving at least one of amplitude and phase and that processes different frequency components that correspond to a range associated with resonant frequencies of scanning frequencies used in the signal having multiple frequency components (e.g., the resonant frequencies being within a predetermined or resonance bandwidth of the scanning frequencies in the signal); using a task-driven algorithm to find the scan-pattern design (e.g., by varying scan-pattern variables according to different possible scan regions in the field of view); and finding an optimal scan-pattern design for the RoI and then providing concentrated spatial sampling or traversing for the RoI.

In certain related aspects, the use of an algorithm to find the scan-pattern design may be based on amplitude and phase parameters in x-axis and y-axis motion in the field of view (e.g., near or in the RoI), and/or based on a sampled scanning pattern defined in part by a set of amplitude parameters used to modulate the multiple frequency components. Further, once samples are obtained in two such axes, the sampling may acquire depth information to form a point cloud, processing circuitry may be used to process the point cloud for multiple down-stream tasks, including but not restricted to, object detection, LiDAR odometry, and 3D reconstruction.

In certain example embodiments, by applying the above-discussed illustration of an example proposed optimization framework for (simulated or actual) 3D environments, sampling may be obtained quickly and in a detailed manner that focuses on a RoI. In certain examples according to the present disclosure, unlike some previous 3D imaging datasets which are acquired with a raster-scanned or a flash LiDAR, one example embodiment is directed to a point cloud generation tool which may be used to generate a point cloud corresponding to a resonant scanning pattern.

As exemplified in more detail below in connection with experimental, proof-of-concept examples, more specific aspects of the present disclosure are directed to one or more of the above-described aspects of scanning through use of a wide-band detection algorithm to control phase accuracy, and/or use of a particular type of mechanical device or system (e.g., MEMS-type device) employing the provided or selected multiple-frequency signal and scan-pattern design. In view of the above, the skilled artisan may appreciate that the term “MEMS” refers to a micro-electro-mechanical system, that scanning the RoI by sampling and traversing the RoI more times than other regions in the field of view, wherein the other regions in the field of view may refer to or include an unsampled region outside of the RoI, and that the afore-mentioned signal, having multiple frequency components and a scan-pattern design with a balanced or optimized set of attributes, refers to or includes a modulated signal.

Turning now to the drawings, the above aspects are discussed in connection with more details below, which details related to the above examples and aspects of the present disclosure, in the form of exemplary embodiments and proof-of-concept efforts and therefore include discussion of conventional-type scanning implementations (e.g., involving baseline patterns and/or single-frequency signals) characterized in contrast to certain of the illustrated and described example embodiments which are merely examples used by the present disclosure to help aid in understanding certain aspects and/or advantages of specific implementations. As such aspects and/or advantages are not applicable to all embodiments, they are not intended to be necessarily limiting.

In certain contexts, “scanning pattern” and “scanning trajectory” may be used interchangeably, in that both may be used to refer to the trajectory of continuous motion of the optical scanner or laser beam deflected by the scanner. The “sampling pattern” may be referred to as the temporally discretized scanning pattern. This temporal discretization may come from the bandwidth of either light source modulation or sensor response.

Conventionally, Lissajous (resonant) scanning is implemented with a 2-axis scanner, each axis actuated at a single frequency close to the resonant frequency fₓ^{r}, f_{y}^{r}. In the following, such scanning patterns are referred to as “baseline”, or “single-frequency”, or unmodulated”, or “non-adaptive”. The x and y scanner motion trajectories are described in equation 1.

$$\{ \begin{matrix}x ( t ) = {H}_{x} ( {f}_{x} ) {A}_{x} cos ( {f}_{x} t + {ϕ}_{x} ) \\ y ( t ) = {H}_{y} ( {f}_{y} ) {A}_{y} cos ( {f}_{y} t + {ϕ}_{y} )\end{matrix} \qquad ( 1 )$$

Where Hₓ and H_{y} are amplitude transfer functions in x and y scanning axes. Ax and Ay are actuation signal amplitudes. fₓ and f_{y} are actuation signal frequencies and ϕₓ and ϕ_{y} are phases.

When the actuation signal contains multiple frequency components, the scanner motion may also contain the same set of frequency components, as expressed in equation 2. In the following, such scanning patterns may be referred to as “multi-frequency”, or “modulated”, or “adaptive”:

$$\{ \begin{matrix}x ( t ) = {\sum }_{n} {α}_{n} {H}_{x} ( \frac{n}{Lm} ) cos ( \frac{n}{Lm} t ) + {γ}_{n} {H}_{x} ( \frac{n}{Lm} ) sin ( \frac{n}{Lm} t ) , & \sqrt{{\sum }_{n} {α}_{n}^{2} + {γ}_{n}^{2}} <= 1 \\ y ( t ) = {\sum }_{k} {β}_{k} {H}_{y} ( \frac{k}{Lm} ) cos ( \frac{k}{Lm} t ) + {δ}_{k} {H}_{y} ( \frac{k}{Lm} ) sin ( \frac{k}{Lm} t ) , & \sqrt{{\sum }_{k} {β}_{k}^{2} + {δ}_{k}^{2}} <= 1\end{matrix} \qquad ( 2 )$$

Where Hₓ and H_{y} are transfer function amplitudes, L is an integer that controls frequency components spacing and m is the frame time. Also, due to the band-pass characteristics of the transfer functions Hₓ and H_{y}, only frequency components close enough to resonant frequencies fₓ^{r}, f_{y}^{r} have a significant impact on scanner motion. Therefore, the number of frequency components does not need to be large.

Equation 2 shows that the scanner motion is linearly determined by the parameter set {αₙ}, {βₖ}, {γₙ}, {δₖ}, which corresponds to the scanner actuation signal amplitude. The magnitudes of these parameters are constraint for compatibility with real-world actuation hardware. Therefore, optimization can be readily performed on the parameter set {αₙ}, {βₖ}, {γₙ}, {δₖ} to “adapt” the scanning trajectory (e.g. focus onto RoI).

In certain example embodiments, time discretization can be applied on equation 2 to get the sampled scanning pattern \vec{x} Σ [symbol] ^{N}, \vec{y} ∈ [symbol] ^{N}, where N is the number of sampling points. Transfer functions Hₓ, H_{y}, resonant frequencies fₓ^{r}, f_{y}^{r} frame time, and/or N may be set as hyper-parameters in optimization.

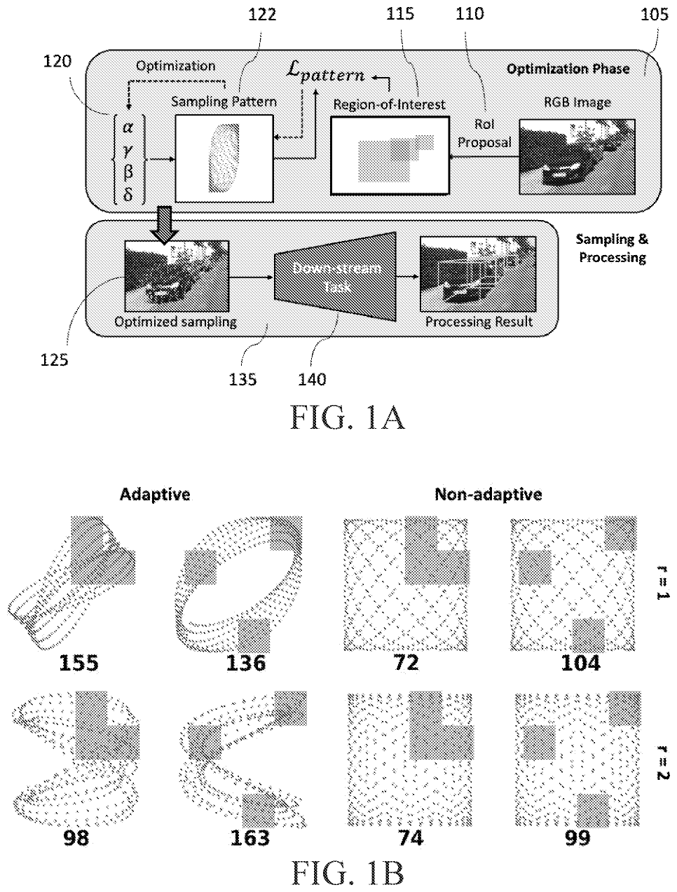

FIG. 1A shows two related sub-block diagrams, which may be used separately or together (e.g., as a single block diagram if used together), useful for illustrating certain aspects and examples relating to the above-characterized scanning apparatuses and methodology according to the present disclosure. The upper portion 105 of FIG. 1A shows an example schematic, as a data flow or pipeline, for providing a balancing or optimization framework, including a desirable pattern design for a targeted RoI. The sampling pattern may be shaped into task-specific or scene-specific RoI-focused patterns through an objective function referred to as a [symbol] ₚₐₜₜₑᵣₙ (discussed further below). In the example of FIG. 1A, the pipeline is shown for a three-dimensional (3D) object detection task. The upper portion 105 of FIG. 1A provides two aspects: RoI-indicating pipeline (as at block 110) (e.g., from an RGB image or other data) to indicate a proposed RoI (as at block 115) within a certain scanning or scannable range (as may be associated with a scanner's field of view or “FoV”); and the parameter set 120 (e.g., {αₙ}, {βₖ}, {γₙ}, {δₖ}) for providing a signal having multiple frequency components and for providing a discretized sampling pattern (as at block 122). These two aspects provide data to a processing circuit (not shown but exemplified and indicated by [symbol] ₚₐₜₜₑᵣₙ) which executes an algorithm that may be executed to find a scan-pattern design with a balanced or optimized set of attributes including a sampling density attribute, preferably a sampling density attribute that overlaps or is optimal to detection within the RoI. This optimization process may be either online (during scanner operation) or offline (conducted beforehand and fixed thereafter). After optimization convergence, the balanced or optimized parameter set are used in the lower portion 135 of FIG. 1A to actuate the scanner and acquire spatial information within the FoV. According, a data processing circuit is shown as being directed to down-stream operations (as at block 140) which involves sampled spatial information from the RoI (with or without other regions in the scanner's field of view).

In the optimization framework, Regions-of-Interest (RoI) may be accommodated through fast processing on a 2D RGB image, or other sensing results and heuristic analysis. The RoI may be represented by a weight map W and its values may correspond to the importance of each regions in the FoV. With x, y and W, the objective function [symbol] ₚₐₜₜₑᵣₙ may be defined in equation 3:

[symbol]

ₚₐₜₜₑᵣₙ=Σ_{i,j}W̅_{i,j}[(xᵢ−[n_{i,j}])²+(yⱼ−y[n_{i,j}])²]. (3)

In equation 3, the [−1,1]×[−1,1] FoV (normalized by the product of amplitudes with on-resonance actuation) is divided into I×J patches. For each patch (i,j), the closest sampling point (x[n_{i,j}], y[n_{i,j}]) to its center location (xᵢ, yᵢ) is obtained and the distance is calculated between these two points. The parameter W̅_{i,j} indicates the importance of each patch and is defined as the average weight in patch (i,j). Patches with larger average weights have a higher priority during optimization. Note that if the distance between patch (i,j) and (x[n_{i,j}], y[n_{i,j}]) is smaller than a threshold, this patch is considered as occupied and W̅_{i,j} is set to zero, regardless the weight value in this patch. From [symbol] ₚₐₜₜₑᵣₙ, gradient descent optimization is performed on the parameter set {αₙ}, {βₖ}, {γₙ}, {δₖ}. Once the optimization is done, spatial sampling can be conducted on a 3D scene, and a sparse point cloud is generated. This point cloud can be used in further 3D computer vision processing, including but not limited to depth inpainting and object detection.

FIG. 1B is chart-based diagram illustrating different types of scanning patterns including those associated with single-frequency scan signals and multiple-frequency scan signals, the latter of which are described as being useful for certain exemplary scanning apparatuses and methodology consistent with aspects of the present disclosure. In left part of FIG. 1B, optimization results of several adaptive Lissajous patterns focused onto specified regions-of-interest (RoI) are shown. The gray blocks in each sub-figure show the RoI. Numbers below each sampling pattern are the sampling density (amount of sampling points) in the RoI. The ratio of resonance frequencies between two scanning axes r=fₓ^{r}/f_{y}^{r} are listed at the right of each row. Comparisons with unmodulated (non-adaptive) Lissajous patterns are shown in the right part of FIG. 1B. As indicated by the sampling density values, adaptive Lissajous patterns sample more points in the specified RoIs. In general situations, the sampling densities are boosted by ˜2× or more.

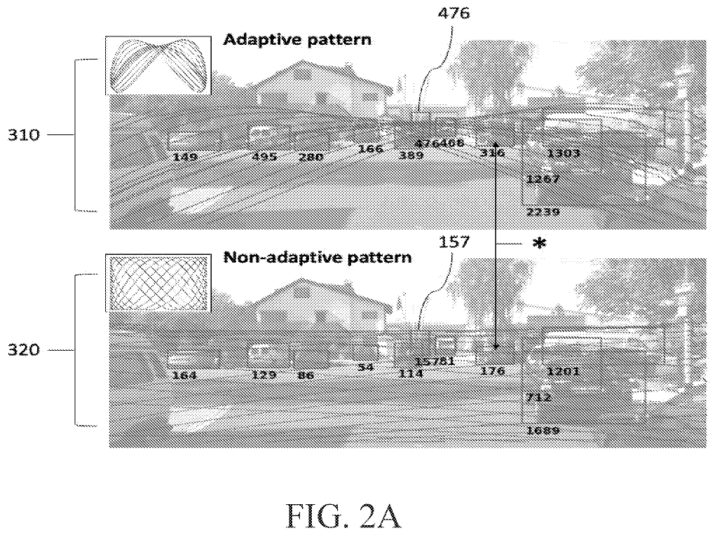

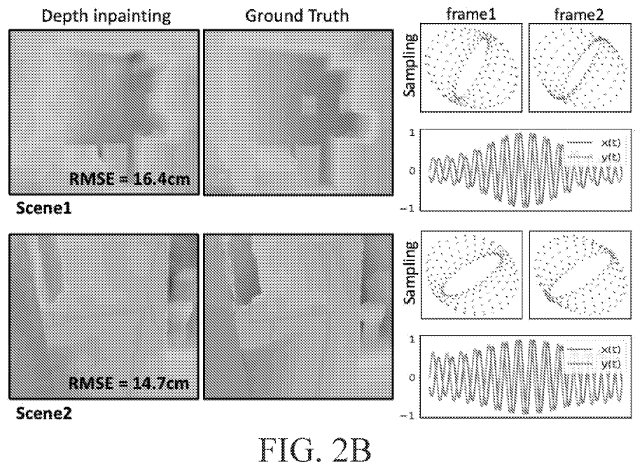

FIG. 2A show qualitative comparison of baseline and design patterns relevant to object-detection estimations of use of these patterns. Object detection is a task that is of interest in 3D computer vision and in connection with certain example embodiments, and is considered an aspect of the present disclosure. For each scene encountered in the task, important objects (e.g., cars, pedestrians) might concentrate in specific regions in the FoV. Therefore, a denser sampling in these Regions-of-Interest (RoI) may be required while sampling outside the RoIs may be redundant, given a fixed total amount of sampling points.

In the example of FIG. 2A, the adaptive scanning pattern is shown in the upper row 310. Each bounding box depicted in FIG. 2A contains an object and the black numbers under each bounding box indicates number of sampling points contained in the bounding box. When compared to the baseline sampling pattern, as in the lower row 320, the optimized pattern samples significantly more points (˜3×) in regions that contain important objects (e.g., cars in this scene). For example, for respective adaptive pattern associated with design pattern and non-adaptive pattern associated with design pattern: the bounding box that is to the right of center in each image (common to each and identified in FIG. 2 using an asterisk, *) indicates the number of sampling points being 316 for the adaptive pattern and 176 for the non-adaptive pattern, and the bounding box just to the right of center indicates the number of sampling points being 476 for the adaptive pattern and 157 for the non-adaptive pattern (and respectively labeled in FIG. 2 as “476” and “157”). This focused sampling largely facilitates the overall object detection process for many such applications of object detection such as in LiDAR applications.

Apart from the example of scanning pattern optimization in object detection, the mechanism of the proposed optimization framework is demonstrated with another computer vision task, depth inpainting, in FIG. 2B. Depth inpainting involves generating a dense depth map (3D reconstruction) from a sparsely sampled point cloud (and optionally, a reference RGB image). Consistent with this disclosure, a state-of-the-art depth inpainting framework is adapted for task-driven scanning pattern optimization.

FIG. 2B also shows examples of modulated waveforms for x(t) and y(t) with associated sampling or scanning patterns. For example, there are two examples of a depth of modulation (e.g., amount of amplitude modulation) between Scene1 and Scene2. The amount of modulation for x(t) and y(t) associated with Scene1 is greater than the amount of modulation for x(t) and y(t) associated with Scene2. The modulated waveforms shown in FIG. 2B includes at least amplitude modulation.

Certain known depth inpainting framework may consist of a rough bilateral filtering stage and a refinement stage. The model may also contain a monocular depth estimator to assist the inpainting task. The whole inpainting algorithm is accomplished by an end-to-end convolutional neural network (CNN), where the bilateral filter is also approximated by an CNN model. In contrast to using that approach, the original bilateral filter is used in the pipeline, and the error-map from this bilateral filter stage is directly used for optimization. This may be implemented to avoid the influence of depth information contained in monocular depth estimation. The advantage of the proposed optimization framework, comparatively, is that RoI information across the whole FoV has an impact on the scanning pattern updating, even when the non-optimized sampling region is small.

Another more-specific experimental-type embodiments of the present disclosure include LiDAR odometry task. LiDAR odometry algorithms estimate the pose and trajectory of an object during navigation. They extract feature points from a 3D point cloud or a 2D image acquired in each frame. By comparing the spatial positions of these feature points between successive frames, pose of the object in a world coordinate can be estimated. In one such example in this context, LiDAR odometry with resonant scanning patterns is considered on a simulated or real dataset, and a state-of-the-art LiDAR odometry framework, named “LOAM”, is adapted for use into the resonant (frequency) scanning scenario. For further information regarding these datasets and other known background aspects, reference may be made to the list of publications in Appendix A of the above U.S. Provisional Application (as examples: Ji Zhang et al., Loam: Lidar Odometry and Mapping in Real-time. Robotics: Science and Systems, Vol. 2, 2014, 2020, IEEE; and Jiarong Lin et al., A Fast, Robust, High-Precision Lidar Odometry and Mapping Package for Lidars of Small FoV, International Conference on Robotics and Automation (ICRA), pages 3126-3131, IEEE, 2020.

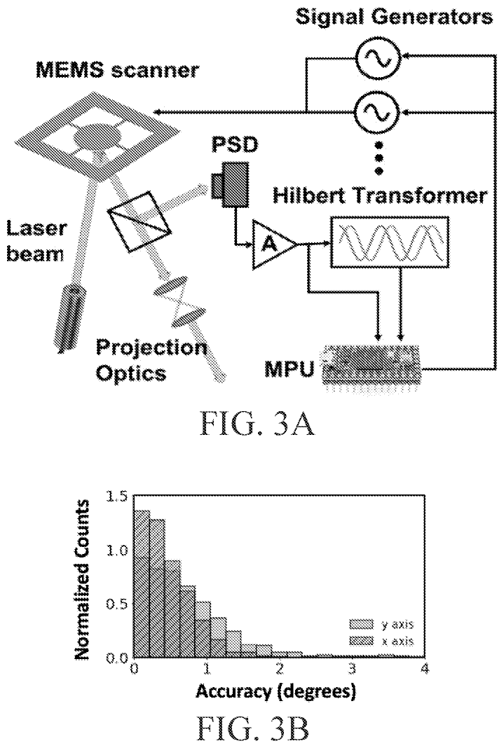

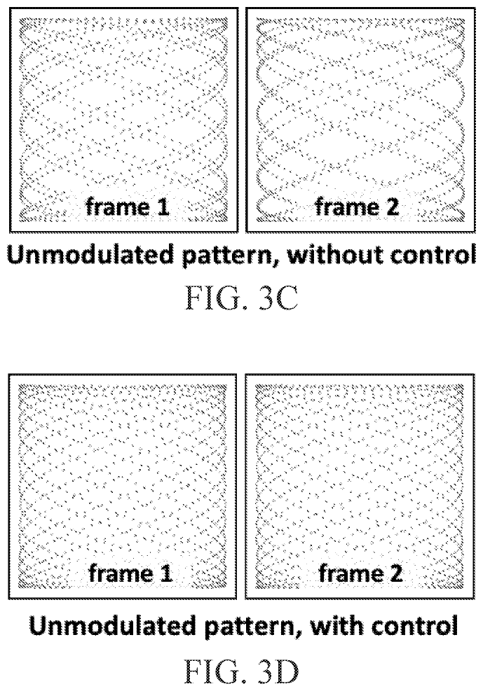

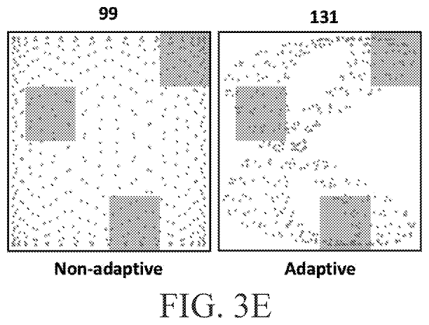

In connection with certain other examples according to the present disclosure, the designed scanning patterns may be implemented in an exemplary hardware prototype. Consistent therewith, FIG. 3A shows a schematic of such an example set up for phase controlled resonant scanning. Other specific aspects for this example embodiment of the present disclosure are shown in FIGS. 3B-3E. FIG. 3B shows phase-control estimations associated with use of this embodiment. FIG. 3C shows recorded baseline scanning pattern, without phase control, for two successive frames, for this embodiment. FIG. 3D shows recorded unmodulated sampling patterns, with control, for two successive frames. Finally, FIG. 3E shows recorded optimized patterns, for comparison, related to these embodiments.

This example embodiment uses a MEMS scanner with resonant frequencies fₓ^{r}=2660 Hz, f_{y}^{r}=1100 Hz, with a resonant frequency ratio r=2.42. The quality factors for the two axes are Q_{X}˜30 and Q_{y}˜50. Since the quality factor for the y-axis is too high, it is actuated with a single frequency, which results in sub-optimal performance of the system as compared to multi-frequency scanning in both axes. Further, a wide-band phase detection and control system are used to eliminate the inherent phase instability in MEMS scanners. With this system, ˜1° phase control accuracy is achieved, as shown in FIG. 3B. To measure the accuracy, detection of the scanner phase is conducted at the beginning of each frame and it is compared to the required phase, within ten minutes of the scanner operation. This calibration may be conducted with a high-speed oscilloscope (not shown in FIG. 3A). The accuracy can be improved with faster MPU (or CPU), or through use of better position-detection hardware. See also further discussion on phase stability (with and without control) hereinbelow.

For phase control, exemplary efforts in connection with the present disclosure demonstrate such control for single frequency scanning. Such efforts may include recording the scanning patterns with a high-speed position sensor (PSD). For example, it may be assumed that each frame=6.4 ms. Scanning patterns with on-resonance actuation (fₓ=2660 Hz, f_{y}=1100 Hz) and without phase control are shown in FIG. 3C, for two successive frames. Most portions of the FoV are either over-sampled or under-sampled. FIG. 3D shows another single-frequency scanning pattern with fₓ=2672 Hz, f_{y}=1100 Hz, ϕₓ=π/14 and ϕ_{y}=0 and with the above-mentioned phase control scheme. This is a demonstration of the phase control scheme being effective and accurate.

Discussion now turns to phase control in multiple-frequency scanning, again involving such efforts in connection with the present disclosure. For one example of a multi-frequency scanning scenario or demonstration, the x-axis of the scanner may be driven at three frequencies, fₓ, 13/14fₓ, 15/14fₓ, and the y-axis may be driven at a single frequency f_{y}. Phases of the three components in the x-axis scanning are monitored and controlled at the beginning of every four frames. Frame time is set to be the same as that in the single frequency scanning experiment. As shown in FIG. 3E, for fₓ=2200 Hz, f_{y}=1100 Hz (r˜2.0), The scanning pattern is focused on to gray color RoI, and sampling densities (black number above sampling pattern) in the RoI increases from 99 (left side, non-adaptive baseline pattern) to 131 (right side, adaptive optimized pattern).

Yet further aspects of efforts supporting the present disclosure concern methodology involving setting up and controlling the phases used in the modulation signals for appropriate use in the above-discussed scanning examples. First, examples of phase control setup are addressed. As shown in FIG. 3A, the MEMS scanner may be actuated with signal generators (e.g., SIGLENT SDG2000X) as controlled by external phase modulation signals. The motion of the MEMS may be detected with a high-speed position sensor (e.g., ON-TRAK OT-301). In one such effort consistent with the above discussion, this motion signal is fed into an analog wide-band (e.g., Hilbert transformer) phase detector board for 90 degrees phase shift. Both motion signals x(t), y(t) and the 90 degrees phase shifted signals x(t), y(t) are sampled with an MPU chip (PJRC Teensy3.6). In this example and in practice, such a phase detector may apply a frequency dependent phase shift on both output signals while the relative phase between these two outputs is fixed to be π/2. A fast processing algorithm is performed on the two signals to get the phase and a feed-back signal is generated to the external modulation port of signal generators.

As for phase estimation process, the related phase calculation may be less complex in the single frequency actuation case. For example, after collecting x(t) and z(t) at the beginning of each frame, a fast arctangent calculation (see Sreeraman Rajan, et al., Efficient approximations for the arctangent function, IEEE Signal Processing Magazine, 23(3):108-111, 2006) may be performed to obtain the phase. The whole detection process may take under 50 us and in one instance as little as about ˜15 us.

For multiple frequencies actuation, phase detection and control is more complicated, since x(t), y(t) and z(t), y(t) both contain multiple frequency components. For purposes of discussion in connection with one example embodiment in this regard, a comparatively simple situation is used, wherein: the x axis actuation contains three frequency components and the y axis contains only single frequency component. Similar methodology can be extended to a more general case. The scanner motion is expressed in the x-axis as:

$$\{ \begin{matrix}x ( t ) = {α}_{0} cos ( {ω}_{x}^{0} t + {ϕ}_{x}^{0} ) + {α}_{1} cos ( {ω}_{x}^{1} t + {ϕ}_{x}^{1} ) + {α}_{2} cos ( {ω}_{x}^{2} t + {ϕ}_{x}^{2} ) \\ \overline{x} ( t ) = {α}_{0} sin ( {ω}_{x}^{0} t + {ϕ}_{x}^{0} ) + {α}_{1} sin ( {ω}_{x}^{1} t + {ϕ}_{x}^{1} ) + {α}_{2} sin ( {ω}_{x}^{2} t + {ϕ}_{x}^{2} )\end{matrix} \qquad ( 5 )$$

As seen in equation 5, there are three phases OX, i=0,1,2. A detection is made at both the beginning of each frame and at the center of each frame to get a set of six equations as follows:

$$\{ \begin{matrix}\begin{matrix}\begin{matrix}\begin{matrix}\begin{matrix}\begin{matrix}x ( 0 ) = {α}_{0} cos ( {ϕ}_{x}^{0} ) + {α}_{1} cos ( {ϕ}_{x}^{1} ) + {α}_{2} cos ( {ϕ}_{x}^{2} ) , \\ x ( {T}_{frame} / 2 ) = {α}_{0} cos ( {ω}_{0} {T}_{frame} / 2 + {ϕ}_{x}^{0} ) + {α}_{1} cos ( {ω}_{1} {T}_{frame} / 2 + {ϕ}_{x}^{1} ) +\end{matrix} \\ {α}_{2} cos ( {ω}_{2} {T}_{frame} / 2 + {ϕ}_{x}^{2} ) ,\end{matrix} \\ x ( {T}_{frame} ) = {α}_{0} cos ( {ω}_{0} {T}_{frame} + {ϕ}_{x}^{0} ) + {α}_{1} cos ( {ω}_{1} {T}_{frame} + {ϕ}_{x}^{1} ) +\end{matrix} \\ {α}_{2} cos ( {ω}_{2} {T}_{frame} + {ϕ}_{x}^{2} ) ,\end{matrix} \\ \overline{x} ( 0 ) = {α}_{0} sin ( {ϕ}_{x}^{0} ) + {α}_{1} sin ( {ϕ}_{x}^{1} ) + {α}_{2} sin ( {ϕ}_{x}^{2} ) ,\end{matrix} \\ \begin{matrix}\begin{matrix}\overline{x} ( {T}_{frame} / 2 ) = {α}_{0} sin ( {ω}_{0} {T}_{frame} / 2 + {ϕ}_{x}^{0} ) + {α}_{1} sin ( {ω}_{1} {T}_{frame} / 2 + {ϕ}_{x}^{1} ) + \\ {α}_{2} sin ( {ω}_{2} {T}_{frame} / 2 + {ϕ}_{x}^{2} ) ,\end{matrix} \\ \begin{matrix}\overline{x} ( {T}_{frame} ) = {α}_{0} sin ( {ω}_{0} {T}_{frame} + {ϕ}_{x}^{0} ) + {α}_{1} sin ( {ω}_{1} {T}_{frame} + {ϕ}_{x}^{1} ) + \\ {α}_{2} sin ( {ω}_{2} {T}_{frame} + {ϕ}_{x}^{2} ) ,\end{matrix}\end{matrix}\end{matrix}$$

As this above equation set is linear in {αᵢ cos(ϕᵢⁱ), αᵢ sin(ϕₓⁱ)}, i=1,2,3, a fast-matrix multiplication can be used to solve them. Then the fast arctangent calculation can be applied on each (cos, sin) pair separately to get the phases. The whole data acquisition and processing, in one experiment, takes less than 100 us (˜40 us in one instance) for three frequency components.

Amplitudes and phases of transfer function Hₓ(fₓ), H_{y}(f_{y}) may also be charted (e.g., as shown in the above-referenced U.S. Provisional Application), for two scanning axis of the MEMS scanner. From the calibration, resonant frequency of the MEMS scanner is determined to be fₓ^{r}=2660 Hz, f_{y}^{r}=1100 Hz. Quality factors are determined from full-width-half-maximum (FWHM) on the transfer function curve, Qₓ˜30, Q_{y}˜50. As may be shown, around resonance, relative phase between MEMS scanner motion and the input actuation signal undergoes a steep transition. Small fluctuations in the resonant frequency would result in large phase drift. This small fluctuation can be due to temperature fluctuations, spring stiffening and other random environmental factors.

This phase instability of the MEMS scanner is characterized when the control system is not used. Further, as may be recorded, the relative phase between the x-axis actuation signal and scanner motion is within 40 minutes. The MEMS scanner in one such example is actuated at a fixed frequency 2660 Hz, with no modulation or control being used. Since the phase of actuation signal (from signal generator) is assumed to be stable enough, the ˜10° phase drift can be attributed to fluctuations in the MEMS scanner.

Accordingly, it is appreciated that as specific examples, the above-characterized figures and discussion are provided to help illustrate certain aspects (and advantages in some instances) which may be used in the manufacture of such structures and devices. These structures and devices include the exemplary structures and devices described in connection with each of the figures as well as other devices, as each such described embodiment has one or more related aspects which may be modified and/or combined with the other such devices and examples as described hereinabove may also be found in the Appendices of the above-referenced Provisional.

The skilled artisan would also recognize various terminology as used in the present disclosure by way of their plain meaning. As examples, the Specification may describe and/or illustrates aspects useful for implementing the examples by way of various circuits which may be illustrated as or using terms such as blocks, devices, system, and other circuit-type depictions. Such circuits and related circuitry may be used together with other elements to exemplify how certain examples may be carried out in the form or structures, steps, functions, operations, activities, etc. It would also be appreciated that terms to exemplify orientation (e.g., upper/lower, left/right, etc.) refer to relative positions of aspects shown in the figures, and merely for notational convenience. The disclosed aspects may be oriented different from the illustrated orientation.

Based upon the above discussion and illustrations, those skilled in the art will readily recognize that various modifications and changes may be made to the various embodiments without strictly following the exemplary embodiments and applications illustrated and described herein. For example, methods disclosed herein (whether described generally or in various degrees of detail) may involve steps carried out in various orders, and may involve fewer or more steps as may be typical and depending on specific implementation requirements.

1. A method comprising:
providing a signal having multiple frequency components and a scan-pattern design with a balanced or optimized set of attributes including a sampling density attribute; and
using the signal and the scan-pattern design to scan a region of interest (RoI) in a field of view by sampling or traversing the RoI more times than other regions in the field of view.

2. The method of claim 1, further including using the field of view to find the scan-pattern design based on an algorithm that processes different parameters involving at least one of amplitude and phase.

3. The method of claim 1, further including finding the scan-pattern design based on an algorithm that processes different parameters involving at least one of amplitude and phase and processes a number of different frequency components related to or including the multiple frequency components, wherein the number of different frequency components is greater than three and less than a threshold limit at which it is assumed that processing different frequency components provides negligible improvement.

4. The method of claim 1, further including finding the scan-pattern design based on an algorithm that processes different parameters involving at least one of amplitude and phase and that processes different frequency components that correspond to a range associated with resonant frequencies of scanning frequencies used in the signal having multiple frequency components.

5. The method of claim 4, wherein the resonant frequencies are within a predetermined or resonance bandwidth of the scanning frequencies in the signal.

6. The method of claim 1, further including finding the scan-pattern design based on a task-driven algorithm that varies scan-patterns variables according to different possible scan regions in the field of view.

7. The method of claim 1, further including using an algorithm that finds the scan-pattern design as being optimal for the RoI, and in response to finding the scan-pattern design as being optimal for the RoI, further including providing concentrated spatial sampling or traversing for the RoI.

8. The method of claim 1, further including using an algorithm that finds the scan-pattern design based on amplitude and phase parameters in x-axis and y-axis motion in the field of view, and wherein the sampling density attribute is associated with the RoI, with an increased number of sample points in the RoI relative to the other regions, to provide focus, within the field of view, on the RoI.

9. The method of claim 1, further including using an algorithm based: on a sampled scanning pattern defined in part by a set of amplitude parameters used to modulate the multiple frequency components; and on a representation of the field of view with the RoI being associated with values more heavily weighted than values associated with the other regions in the field of view.

10. The method of claim 9, further including: using the set of amplitude parameters to modulate the multiple frequency components in two dimensions of the field of view; and, in response to using said algorithm based on a sampled scanning pattern and on a representation of the field of view, conducting spatial sampling or traversing in a third dimension of the field of view and generating therefrom a point cloud wherein the spatial sampling or traversing is more concentrated in the RoI than the other regions.

11. The method of claim 1, wherein said using the signal and the scan-pattern design to scan includes using a MEMS scanner with resonant frequencies that are associated with scanning frequencies used in the signal.

12. The method of claim 1, wherein said using the signal and the scan-pattern design to scan includes using: a MEMS scanner; and a wide-band detection algorithm to control phase accuracy while using the MEMS scanner.

13. The method of claim 1, further including scanning the RoI by sampling and traversing the RoI more times than other regions in the field of view, wherein the field of view includes an unsampled region outside of the RoI, and wherein said signal is a modulated signal.

14. A method comprising:
generating or providing a scan-pattern design with a balanced or optimized set of attributes including a sampling density attribute, wherein the scan-pattern design is configured or optimized for use with a signal having multiple frequency components, such that the signal and the scan-pattern design are cooperatively configured to scan a region of interest (RoI) in a field of view by sampling or traversing the RoI more times than other regions in the field of view.

15. An apparatus comprising:
signal-generation circuitry to provide a signal having multiple frequency components and a scan-pattern design with balanced or optimized set of attributes including a sampling density attribute; and
scan circuitry to use the signal and the scan-pattern design to scan a region of interest (RoI) in a field of view by sampling or traversing the RoI more times than other regions in the field of view.

16. The apparatus of claim 15, further including sampling and processing circuitry to use the field of view to find the scan-pattern design based on an algorithm that processes different parameters involving at least one of amplitude and phase.

17. The apparatus of claim 15, further including processing circuitry to find the scan-pattern design based on an algorithm that processes different parameters involving at least one of amplitude and phase and processes a number of different frequency components related to or including the multiple frequency components, wherein the number of different frequency components is greater than two and less than an threshold limit at which it is assumed that processing different frequency components provides negligible improvement.

18. The apparatus of claim 15, further including processing circuitry to find the scan-pattern design based on an algorithm that processes different parameters involving at least one of amplitude and phase and that processes different frequency components that correspond to a range associated with resonant frequencies of scanning frequencies used in the signal.

19. The apparatus of claim 18, wherein the resonant frequencies are within a predetermined or resonance bandwidth of the scanning frequencies in the signal.

20. The apparatus of claim 18, further including processing circuitry to find the scan-pattern design based on a task-driven algorithm that varies scan-patterns variables according to different possible scan regions in the field of view.

21. The apparatus of claim 18, further including processing circuitry to execute an algorithm for finding the scan-pattern design as being optimal for the RoI, and in response to finding the scan-pattern design as being optimal for the RoI, further including providing concentrated spatial sampling or traversing for the RoI.

22. The apparatus of claim 18, further including processing circuitry to execute an algorithm for finding the scan-pattern design based on amplitude and phase parameters in x-axis and y-axis motion in the field of view.

23. The apparatus of claim 18, further including processing circuitry to execute an algorithm based: on a sampled scanning pattern defined in part by a set of amplitude parameters used to modulate the multiple frequency components; and on a representation of the field of view with the RoI being associated with values more heavily weighted than values associated with the other regions in the field of view.

24. The apparatus of claim 23, wherein at least one of the signal-generation circuitry and the scan circuitry is to use the set of amplitude parameters to modulate the multiple frequency components in two dimensions of the field of view; and, in response to using said algorithm based on a sampled scanning pattern and on a representation of the field of view, conducting spatial sampling or traversing in a third dimension of the field of view and generating therefrom a point cloud wherein the spatial sampling or traversing is more concentrated in the RoI than the other regions.

25. The apparatus of claim 18, further including a MEMS scanner, including the scan circuitry, to perform the scan.

26. The apparatus of claim 25, further including processing circuitry to perform a wide-band detection algorithm to control phase accuracy while using the MEMS scanner.

27. The apparatus of claim 18, further including a LiDAR (light detection and ranging) circuit which is integrated with the signal-generation circuitry and the scan circuitry.
